(19) United States
(12) Patent Application Publication
(10) Pub. No.: US 2024/0128106 A1
(43) Pub. Date: Apr. 18, 2024

(54) CONTAINER FOR NON-RECTANGULAR RETICLE

(71) Applicant: GUDENG PRECISION INDUSTRIAL CO., LTD., New Taipei (TW)

(72) Inventors: Ming-Chien CHIU, NEW TAIPEI (TW); Chia-Ho CHUANG, NEW TAIPEI (TW); Hsin-Min HSUEH, NEW TAIPEI (TW); Yu-Ruei CHEN, NEW TAIPEI (TW)

(21) Appl. No.: 18/370,998

(22) Filed: Sep. 21, 2023

Related U.S. Application Data
(60) Provisional application No. 63/416,016, filed on Oct. 14, 2022.

(51) Int. Cl. H01L 21/673

(52) U.S. Cl. CPC H01L 21/67359; H01L 21/67386

(57) ABSTRACT

The invention discloses a container for a non-rectangular reticle, adapted for accommodating an elliptical reticle, and including a cover and a base which are configured to define an elliptical space when engaged with each other. The cover and the base have reticle retainers and reticle supports, respectively, which are configured to securely hold the elliptical reticle.

### CROSS-REFERENCE TO RELATED APPLICATIONS

This divisional application claims priority under 35 U.S.C. § 119(a) on Patent Application No. 63/416,016 filed in U.S. on Oct. 14, 2022 the entire contents of which are hereby incorporated by reference.

### BACKGROUND OF THE INVENTION

### Field of the Invention

The present disclosure relates to reticle containers, and more particularly to a container dedicated to holding a non-rectangular reticle.

### Description of the Prior Art

Conventional reticles for use in EUV processes are always square or rectangular in shape. However, unlike quadrilateral reticles, elliptical (and circular) reticles are easy to manufacture in terms of their bodies, coatings and pellicles and thus conducive to the enhancement of the precision and production yield of the reticles. Thus, elliptical (and circular) reticles may be a good option in the future. Conventional EUV reticle pods are designed according to quadrilateral reticles and dedicated to holding the quadrilateral reticles instead of elliptical reticles.

Therefore, it is imperative to provide a container dedicated to holding an elliptical reticle.

### SUMMARY OF THE INVENTION

The disclosure provides a container for a non-rectangular reticle, adapted to hold an elliptical reticle. The container for a non-rectangular reticle comprises a cover and a base. The cover comprises an inner surface and a compartment wall extending downward from the inner surface. The inner surface and the compartment wall define an elliptical space. The cover further comprises a plurality of reticle retainers partially extending into the compartment wall and the elliptical space to abut against an edge of the elliptical reticle. The base is coupled to the cover to define an elliptical receiving space for receiving the elliptical reticle and has a plurality of reticle supports for supporting a bottom of the elliptical reticle.

In a specific embodiment, the base has a ring groove, and the reticle supports each span the ring groove.

In a specific embodiment, the ring groove divides the base into an internal region and an external region, and the internal region is an elliptical region.

In a specific embodiment, the reticle supports each have a supporting block for supporting the bottom of the elliptical reticle and an edge restraint for restraining the elliptical reticle, with the supporting block being in the internal region of the base, and the edge restraint being in the external region of the base.

In a specific embodiment, the reticle retainers of the cover each have an axis of symmetry pointing to a center of the elliptical space of the cover, and the reticle supports of the base each have an axis of symmetry pointing to a center of the internal region of the base.

The disclosure further provides a container for a non-rectangular reticle, adapted to hold an elliptical reticle. The container for a non-rectangular reticle comprises a base and a cover. The base has a load-supporting surface and a plurality of reticle supports disposed at the periphery of the load-supporting surface and adapted to support the elliptical reticle. The cover is coupled to the base to define an elliptical receiving space for receiving the elliptical reticle. The cover comprises a plurality of reticle retainers for restraining the elliptical reticle. The elliptical receiving space is defined by a plurality of curved edges of an inner surface of the base and a plurality of curved edges of an inner surface of the cover.

In a specific embodiment, the load-supporting surface has a plurality of first curved edges, and the reticle supports are each disposed between adjacent ones of the plurality of first curved edges.

In a specific embodiment, a lower surface of the cover has a plurality of second curved edges, and the reticle retainers are each disposed between adjacent ones of the plurality of second curved edges.

In a specific embodiment, the inner surface of the cover has a stepped structure formed from a compartment wall and an inner surface of the cover, and the stepped structure has the plurality of second curved edges.

In a specific embodiment, the base has a ring groove extending along the periphery of the load-supporting surface, and the reticle supports of the base each span the ring groove. The stepped structure and the ring groove are concentric.

The disclosure further provides a reticle storage box comprising a casing and a door. The casing and the door define a storage space for storing the container.

The aforesaid aspects and other aspects of the disclosure are illustrated by non-restrictive, specific embodiments, depicted by accompanying drawings, described below and thus rendered clearer.

### BRIEF DESCRIPTION OF THE DRAWINGS

The disclosure is depicted by drawings, illustrated by non-restrictive, non-exhaustive embodiments, and described below. The drawings are not drawn to scale but are aimed at disclosing the structural features and principles of the disclosure.

FIG. 1 is an exploded view of a container for a non-rectangular reticle and an outer pod according to the disclosure.

FIG. 1A is another exploded view of the container for a non-rectangular reticle according to the disclosure.

FIG. 2 is a perspective view of a cover of the container for a non-rectangular reticle according to the disclosure.

FIG. 3 is a bottom view of the cover of the container for a non-rectangular reticle according to the disclosure.

FIG. 4 is a partial enlarged view, showing an inner surface of the cover.

FIG. 5 is a perspective view of a reticle retainer of the cover of the container for a non-rectangular reticle according to the disclosure.

FIG. 6 is a top view of a base of the container for a non-rectangular reticle according to the disclosure.

FIG. 7 is a perspective view of a reticle support of the base of the container for a non-rectangular reticle according to the disclosure.

FIG. 8A is a partial, enlarged cross-sectional view of the base, showing a reticle lying on the base and supported by the reticle support.

FIG. 8B is a partial, enlarged cross-sectional view of the cover and the base, showing that the reticle is confined to the container by the reticle retainer and the reticle support.

FIG. 9A through FIG. 9C are schematic views of the arrangement of the reticle retainer or the reticle support in variant embodiments of the disclosure.

### DETAILED DESCRIPTION OF THE EMBODIMENTS

The disclosure is depicted by accompanying drawings, illustrated by specific embodiment and described below. However, the subject matter claimed by the disclosure can be implemented in various ways; hence, the subject matter falling within the scope of or claimed by the disclosure is not restricted to any specific embodiments of the disclosure. The specific embodiments of the disclosure serve illustrative purposes only. Likewise, the disclosure is aimed at defining reasonably broad scope of the subject matter falling within the scope of or claimed by the disclosure. Furthermore, for example, the subject matter claimed by the disclosure can be implemented by a method, device or system.

The expression “an embodiment” used herein does not necessarily refer to the same specific embodiment. Likewise, the expressions “another embodiment,” “some embodiments” and “other embodiments” used herein do not necessarily refer to different specific embodiments. Therefore, for example, the claimed subject matter falls within the scope of a combination of exemplary, specific embodiments, in whole or in part. The expression “inner surface” used herein refers to the inner surface of the container; for example, the inner surface of the cover and the inner surface of the base are the hidden parts of the cover and base coupled together.

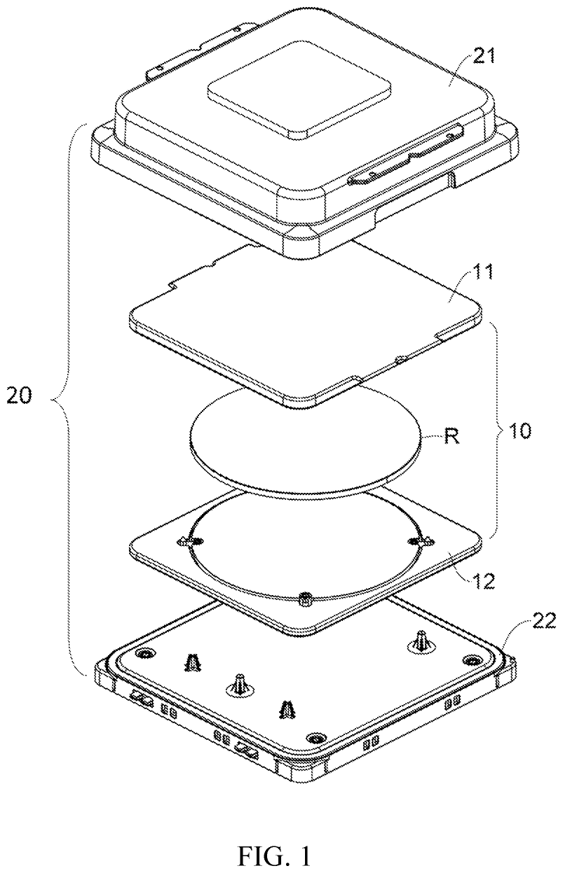

FIG. 1 is an exploded view of a container (10) for a non-rectangular reticle and an outer pod (20) according to the disclosure. FIG. 1A is another exploded view of the container (10) for a non-rectangular reticle according to the disclosure, showing the inner surface of the container (10) for a non-rectangular reticle. The container (10) for a non-rectangular reticle comprises a cover (11) and a base (12) which together define a receiving space for receiving a non-rectangular reticle or an elliptical reticle (R). The outer pod (20) comprises a casing (21) and a door (22) which together define a receiving space for receiving the container (10) for a non-rectangular reticle.

The non-rectangular shape is an elliptical shape with a long axis and a short axis. When the long axis and the short axis are equal, the elliptical shape is a circle. The non-rectangular shape is a polygon with an even or odd number of sides, for example, hexagon, octagon and nonagon. Alternatively, the non-rectangular shape is demarcated by a plurality of curves.

According to the disclosure, the container (10) for a non-rectangular reticle can be implemented in any other forms. For example, a pair of wing portions protruding outward is disposed at edges of the cover (11), and a gas filtering component is disposed at the top of the cover (11). After being coupled together, the cover (11) and the base (12) attain a certain degree of effective airtightness with a conventional, well-known means of airtightness to stop contaminants from intruding into the receiving space via a contact interface between the cover (11) and the base (12).

The outer pod (20) is conventional and well known, for example, with a pair of wing portions protruding outward and flanking the casing (21), a downward-pressing mechanism adapted to abut against and fasten the cover (11) and disposed on the inner surface of the casing (21), an operable locking mechanism adapted to couple the door (22) and the casing (21) together and disposed at the door (22), and a gaseous valve mounted on the door (22) and adapted to perform gas feeding or gas discharging to control the environment and pressure of the receiving space. After being coupled together, the casing (21) and the door (22) attain a certain degree of effective airtightness with a conventional, well-known means of airtightness to maintain the cleanness of the receiving space.

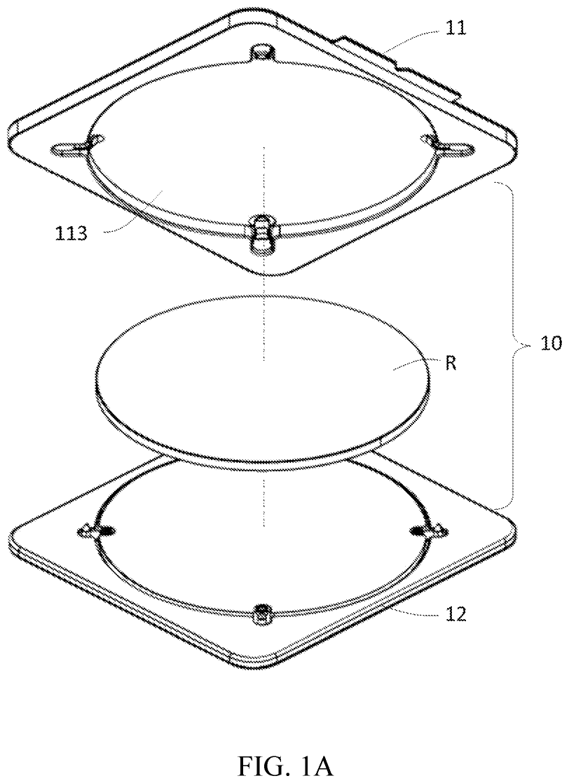

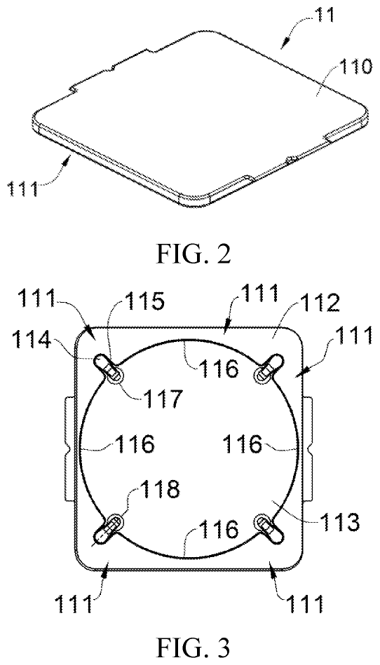

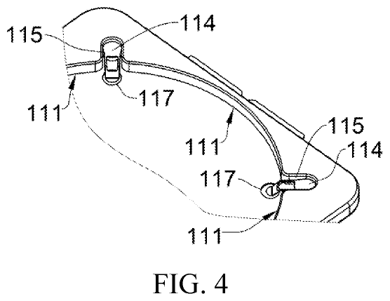

FIG. 2 is a perspective view of the cover (11). FIG. 3 is a bottom view of the cover (11). FIG. 4 is a partial enlarged view, showing an inner surface of the cover. The cover (11) has an outer surface (110) which is basically a smooth surface. The outer surface (110) of the cover (11) faces away from the inner surface of the cover (11) but faces the inner surface of the base (12). The cover (11) has a compartment wall (111) which extends downward from the outer surface (110). The compartment wall (111) defines the surrounding sidewalls of the cover (11) and has a lower surface (112) adapted to come into contact with the base (12). A vertical thickness of the compartment wall (111) is greater than a thickness of the other portions (i.e., the inner surface) of the cover (11), thereby forming a stepped structure. The stepped structure defines a space, especially an elliptical space (113). The elliptical space has a short axis or a diameter greater than a long axis of an elliptical reticle or a diameter of a circular reticle.

A plurality of reticle retainers (114) are disposed between the compartment wall (111) and the elliptical space (113). A portion of each of the reticle retainers (114) extends into the elliptical space (113). A plurality of extension spaces (115) are disposed around the elliptical space (113) and extended toward the compartment wall (111) to accommodate the reticle retainers (114). Furthermore, a plurality of curved edges (116) are each jointly defined by a corresponding one of the extension spaces (115) and the inner surface of the compartment wall (111). The reticle retainers (114) are each disposed between two adjacent ones of the plurality of curved edges (116). A portion of each of the reticle retainers (114) is exposed from the elliptical space (113) to abut against and fasten the edges of the reticle, as shown in FIG. 3.

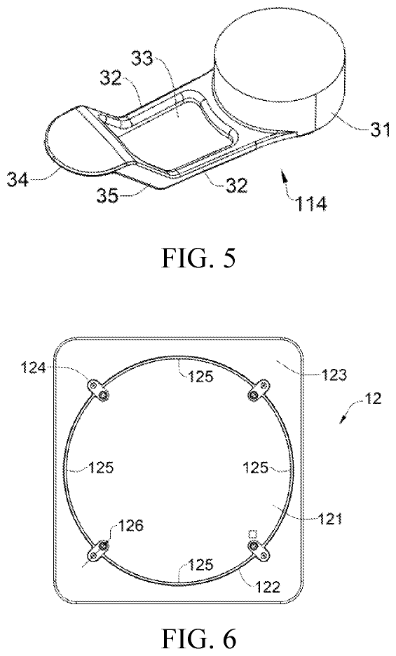

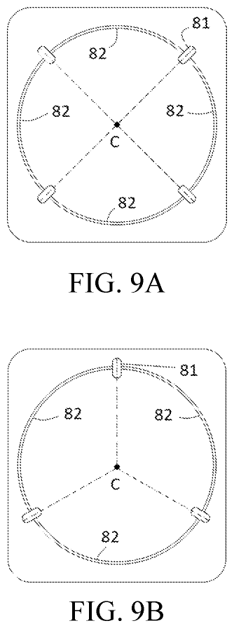

FIG. 5 is a perspective view of one of the reticle retainers (114). As shown in the diagram, the reticle retainer (114) comprises a fixing portion (31) and a resilient leg (32). The reticle retainer (114) is fixed to the inner surface of the cover (11) by the fixing portion (31). The fixing portion (31) is implemented in the form of a conventional, well-known means of fixation, such as a screw or a quick-release mechanism, to ensure that the reticle retainer (114) can be firmly fastened in place. The resilient leg (32) extends laterally from the fixing portion (31) and has a hollowed-out portion (33) and an abutting portion (34). The hollowed-out portion (33) enables the resilient leg (32) to circumvent constituent elements of the base (12). The abutting portion (34) is disposed at the free end of the resilient leg (32) to abut against the upper surface of the reticle, as shown in FIG. 8B. The resilient leg (32) further comprises an oblique extending portion (35) with a guiding surface for restraining, abutting against and fastening upper edges of the reticle.

When the reticle retainer (114) is mounted in place, the fixing portion (31) is basically positioned at the free end of the extension space (115) and surrounded by the compartment wall (111), whereas the resilient leg (32) is partially exposed from the elliptical space (113). Referring to FIG. 4 and FIG. 8B, a buffer space (117) is formed on the inner surface of the cover (11) and positioned proximate to the resilient leg (32) and the abutting portion (34) to preclude structural interference otherwise arising from deformation of the inner surface of the cover (11) and the resilient leg (32) under an applied force.

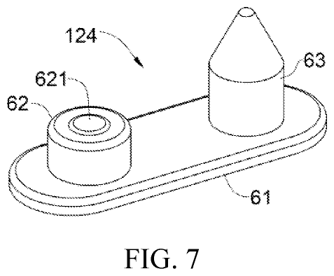

FIG. 6 is a top view of the base (12). As shown in the diagram, the base (12) has a load-supporting surface (121) facing the cover (11). The base (12) is divided into an internal region and an external region (123) by a groove (122) or a stepped structure. The internal region coincides with the load-supporting surface (121). The external region (123) surrounds the load-supporting surface (121) and is mostly in contact with the lower surface (112) of the cover (11). The load-supporting surface (121) and the upper surface of the external region (123) are basically flat with a difference in the vertical height therebetween; in particular, the load-supporting surface (121) is higher than the upper surface of the external region (123). A short axis or a diameter of the load-supporting surface (121) elliptical or circular in shape is slightly less than a short axis or a diameter of the elliptical reticle.

A plurality of reticle supports (124) are disposed between the load-supporting surface (121) and the external region (123). Referring to FIG. 8A, a plurality of recesses (120) are disposed between the load-supporting surface (121) and the external region (123) and adapted to accommodate the reticle supports (124). Basically, the groove (122) is a ring groove that surrounds the load-supporting surface (121). The positions of the reticle supports (124) are on the ring-shaped path of the groove (122); in other words, the reticle supports (124) each span the groove (122) between the load-supporting surface (121) and the external region (123). The load-supporting surface (121) has a plurality of curved edges (125), and the reticle supports (124) are each disposed between adjacent ones of the plurality of curved edges (125). A portion of each of the reticle supports (124) is positioned proximate to the load-supporting surface (121), and the other portion of the reticle support (124) is positioned proximate to the external region (123).

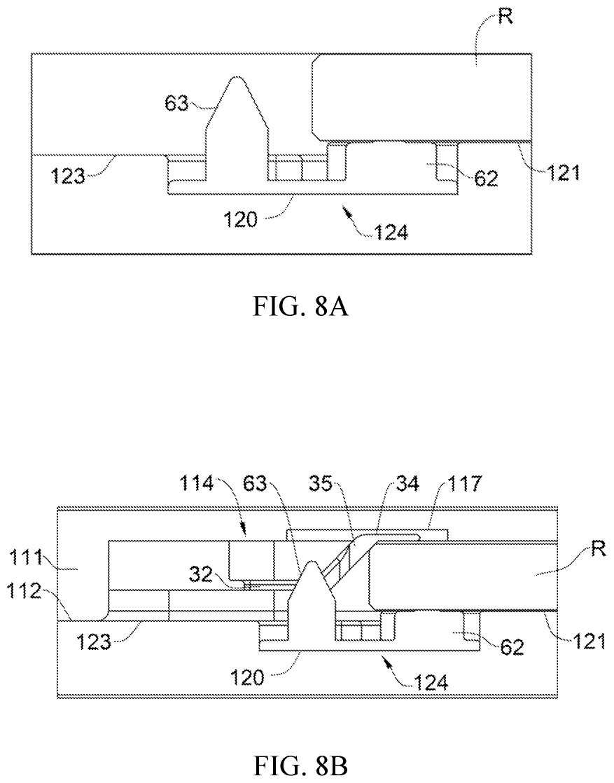

FIG. 7 is a perspective view of one of the reticle supports (124). The reticle support (124) comprises a pad (61), a supporting block (62) and an edge restraint (63). The pad (61) is of an appropriate thickness and shape so as to be fitted in and accommodated in a corresponding one of the recesses (120) of the base (12). The supporting block (62) and the edge restraint (63) extend upward from the pad (61) and are of different heights. The supporting block (62) is positioned proximate to the load-supporting surface (121). A bump (621) is disposed at the top of the supporting block (62) and is slightly higher than the load-supporting surface (121). The edge restraint (63) is positioned proximate to the external region (123) and adapted to prevent the elliptical reticle (R) from shifting to the external region (123), as shown in FIG. 8A. A conical structure is defined at the top of the edge restraint (63) to prevent the corners of the reticle from vibrating under an applied force, detaching from the supporting block (62) and hitting the inner surface of the cover (11).

Referring to FIG. 3 and FIG. 6, each of the reticle retainers (114) and the reticle supports (124) has a symmetric structure and thus has an axis of symmetry (118, 126). An axis of symmetry (118) of the reticle retainer (114) depends on the symmetry of the fixing portion (31) and the resilient leg (32). An axis of symmetry (126) of the reticle support (124) depends on the symmetry of the supporting block (62) and the edge restraint (63). In this embodiment, the axis of symmetry (118) of the reticle retainer (114) and the axis of symmetry (126) of the reticle support (124) point to a center of the elliptical space (113) of the cover (11) and a center of the load-supporting surface (121) of the base (12), respectively. The center is defined as an intersection of the long axis and the short axis of the elliptical shape or a center of the circular shape.

FIG. 8A is a partial, enlarged cross-sectional view of the base (12), showing an elliptical reticle (R) lying on the base (12) and supported by the supporting block (62). FIG. 8B is a partial, enlarged cross-sectional view of the cover (11) and the base (12), showing that the elliptical reticle (R) is confined to the container by the reticle retainer (114) and the reticle support (124).

When the elliptical reticle (R) is rested on the base (12), the bottom of the elliptical reticle (R) is supported by the supporting block (62) such that a tiny gap is formed between the bottom of the elliptical reticle (R) and the load-supporting surface (121). The edge restraint (63) restrains the edges of the elliptical reticle (R) and prevents the edges of the elliptical reticle (R) from shifting to the external region (123). Referring to FIG. 3 and FIG. 6, the reticle retainers (114) of the cover (11) correspond in position to the reticle supports (124) of the base (12) to allow the reticle retainers (114) to be substantially above the reticle supports (124) when the cover (11) and the base (12) are coupled together. Referring to FIG. 5, the top of the edge restraint (63) of the reticle support (124) can penetrate the hollowed-out portion (33) of the resilient leg (32) of the reticle retainer (114) to preclude the structural interference between the reticle retainer (114) and the reticle support (124) and optimize space usage. In another embodiment, the resilient leg (32) does not have the hollowed-out portion (33), but the resilient leg (32) is appropriately designed to preclude structural interference from the edge restraint (63).

Referring to FIG. 8B, the abutting portion (34) abuts against the upper surface of the elliptical reticle (R), and the guiding surface of the oblique extending portion (35) abuts against the upper edges of the elliptical reticle (R), so as to restrain the vertical and lateral displacement of the elliptical reticle (R). The buffer space (117), formed on the inner surface of the cover (11) as mentioned before, is a shallow trench that extends inward from the inner surface of the cover (11) and sufficiently allows the reticle retainer (114) to deform. A tiny difference in dimensions between the elliptical reticles (R) affects the magnitude of deformation of the resilient leg (32) of each reticle retainer (114). The buffer space (117) provides the tolerance of displacement of the abutting portion (34) upon deformation of the reticle retainer (114) to preclude collisions of the abutting portion (34) and the cover (11) and resultant generation of particle contaminants.

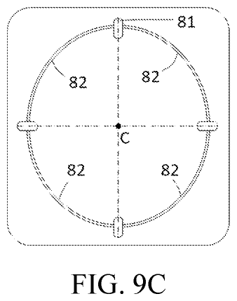

FIG. 9A through FIG. 9C schematically depict variant embodiments of arrangement of the reticle retainers (114) or reticle supports (124). According to the disclosure, both the inner surface of the cover (11) and the inner surface of the base (12) have curved edges. As mentioned before, the inner surface of the compartment wall (111) of the cover (11) has a plurality of curved edges (116), and a plurality of curved edges (125) are defined at a periphery of the load-supporting surface (121) of the base (12). The variant embodiments illustrate multiple combinations of the curved edges (116, 125), the reticle retainers (114) and the reticle supports (124).

FIG. 9A schematically depicts how positions (81) of four reticle retainers or reticle supports relate to four curved edges (82). As shown in the diagram, each of the positions (81) lies between two adjacent curved edges (82), whereas the four curved edges (82) divide the cover or the base into an internal region circular in shape and an external region.

FIG. 9B schematically depicts how the positions (81) of three reticle retainers or reticle supports relate to three curved edges (82). As shown in the diagram, each of the positions (81) lies between two adjacent curved edges (82), whereas the three curved edges (82) divide the cover or the base into an internal region circular in shape and an external region.

FIG. 9C schematically depicts how the positions (81) of four reticle retainers or reticle supports relate to four curved edges (82). As shown in the diagram, each of the positions (81) lies between two adjacent curved edges (82), whereas the four curved edges (82) divide the cover or the base into an internal region elliptical in shape and an external region.

The differences between FIG. 9A and FIG. 9C are described below. The curved edges (82) in FIG. 9A are part of the edges of a circular shape, and the curved edges (82) in FIG. 9C are part of the edges of an elliptical shape. Furthermore, as shown in FIG. 9A, the positions (81) correspond in position to the four corners of the base (12) or the cover (11). As shown in FIG. 9C, the positions (81) correspond in position to the long axis and short axis of an elliptical shape. Likewise, referring to FIG. 9A through FIG. 9C, all the axes of symmetry of the reticle retainers or reticle supports at the positions (81) point to a center (C) of the load-supporting surface or the elliptical receiving space.

Therefore, according to the disclosure, the inner surface of the cover (11) has curved edges (116), whereas the inner surface of the base (12) has curved edges (125), allowing the inner surface of the cover (11) to define the elliptical space. Furthermore, when the cover (11) and the base (12) are coupled together, the curved edges (116) of the inner surface of the cover (11) and the curved edges (125) of the inner surface of the base (12) define a receiving space in elliptical shape or any shape for receiving a non-rectangular reticle.

Although the disclosure is disclosed above by specific embodiments, the specific embodiments are not restrictive of the disclosure. Various changes made by persons skilled in the art to the specific embodiments without departing from the spirit of the disclosure and the scope of the claims of the disclosure must be deemed falling within the scope of the claims of the disclosure. Accordingly, the spirit and the real scope of the claims of the disclosure should be defined by the appended claims.

What is claimed is:

1. A container for a non-rectangular reticle, adapted to hold an elliptical reticle, comprising:
a cover comprising:
an inner surface and a compartment wall extending downward from the inner surface, wherein the inner surface and the compartment wall define an elliptical space; and
a plurality of reticle retainers partially extending into the elliptical space to abut against an edge of the elliptical reticle; and
a base coupled to the cover to define an elliptical receiving space for receiving the elliptical reticle, the base has a plurality of reticle supports for supporting a bottom of the elliptical reticle.

2. The container of claim 1, wherein the base has a ring groove, and the plurality of reticle supports span the ring groove.

3. The container of claim 2, wherein the ring groove divides the base into an internal region and an external region, and the internal region is an elliptical region.

4. The container of claim 3, wherein each of the plurality of reticle supports have a supporting block for supporting a bottom of the elliptical reticle and an edge restraint for restraining the elliptical reticle, with the supporting block being in the internal region of the base, and the edge restraint being in the external region of the base.

5. The container of claim 4, wherein each of the plurality of reticle retainers of the cover have an axis of symmetry pointing to a center of the elliptical space of the cover, and each of the plurality of reticle supports of the base have an axis of symmetry pointing to a center of the internal region of the base.

6. A reticle storage box, comprising:
a casing and a door together defining a storage space for storing the container of claim 1.

7. A container for a non-rectangular reticle, adapted to hold an elliptical reticle, comprising:
a base having:
a load-supporting surface; and
a plurality of reticle supports disposed at a periphery of the load-supporting surface and adapted to support the elliptical reticle; and
a cover coupled to the base to define an elliptical receiving space for receiving the elliptical reticle, the cover comprising a plurality of reticle retainers for restraining the elliptical reticle,
wherein the elliptical receiving space is defined by a plurality of curved edges of an inner surface of the base and a plurality of curved edges of an inner surface of the cover.

8. The container of claim 7, wherein the load-supporting surface has a plurality of first curved edges, and each of the plurality of reticle supports are disposed between adjacent ones of the plurality of first curved edges.

9. The container of claim 7, wherein a lower surface of the cover has a plurality of second curved edges, and each of the plurality of reticle retainers are disposed between adjacent ones of the plurality of second curved edges.

10. The container of claim 9, wherein the inner surface of the cover has a stepped structure formed from a compartment wall and an inner surface of the cover, and the stepped structure has the plurality of second curved edges.

11. The container of claim 10, wherein the base has a ring groove extending along the periphery of the load-supporting surface, and the reticle supports of the base each span the ring groove, wherein the stepped structure of the cover and the ring groove of the base are concentric.

12. The container of claim 7, wherein both the reticle retainers and the reticle supports having axes of symmetry, and the axes of symmetry of the reticle supports and the reticle retainers respectively point to a center of the cover and a center of the load-supporting surface.

13. The container of claim 12, wherein each of the plurality of reticle retainers have a fixing portion and a resilient leg which together define the axis of symmetry of the reticle retainers.

14. The container of claim 12, wherein the reticle supports each have a supporting block and an edge restraint which together define the axis of symmetry of the reticle supports.

15. A reticle storage box, comprising:
a casing and a door together defining a storage space for storing the container of claim 7.
